(19) United States
(12) Patent Application Publication
(10) Pub. No.: US 2010/0071766 A1
(43) Pub. Date: Mar. 25, 2010

(54) Semiconductor device having a multi-layer substrate and a method of forming the semiconductor device

(75) Inventors: Joachim Doehler, White Lake, MI (US); Scott Jones, Romeo, MI (US); Kevin Hoffman, Sterling Heights, MI (US); Tongyu Liu, Dearborn, MI (US)

Correspondence Address: ENERGY CONVERSION DEVICES, INC., 2956 WATERVIEW DRIVE, ROCHESTER HILLS, MI, 48309, US

(73) Assignee: United Soalr Ovonic LLC

(21) Appl. No.: 12/284,557

(22) Filed: Sep. 23, 2008

(51) Int. Cl. H01L 31/0352; H01L 29/82; H01L 31/18

(52) U.S. Cl. 136/258; 257/421; 438/57; 257/E29.323; 257/E31.032

(57) ABSTRACT

A semiconductor device is provided in accordance with an exemplary embodiment. The semiconductor device includes a semiconductive layer disposed over a multi-layer substrate. The multi-layer substrate includes a plurality of dissimilar regions, one of which is an inner magnetic region and the remainder of the multi-layer substrate is thermally symmetrical about the inner magnetic region.

### FIELD OF THE INVENTION

This invention relates generally to a semiconductor device having a multi-layer substrate that includes a plurality of dissimilar regions. In particular, this invention relates to a semiconductor device having a multi-layer substrate that includes a plurality of dissimilar regions, wherein at least one of the regions is an inner region having magnetic properties.

### BACKGROUND OF THE INVENTION

Generally, semiconductor devices have a plurality of materials disposed over a substrate. To maintain the operational integrity of the semiconductor device it is desirable to minimize or eliminate corrosion of the substrate.

In certain semiconductor devices, it is desirable to form at least portions of the semiconductor device utilizing a roll-to-roll manufacturing process wherein, for example, a roll of a continuous substrate is directed through equipment configured to perform processes in the formation of the semiconductor device. After the processing is complete, the processed continuous substrate is then formed into a roll of finished or semi-finished semiconductor devices. During the roll-to-roll processing, a substrate having magnetic properties can be utilized with a magnetic field applied across the substrate to guide and control the position/movement of the substrate as it moves through the equipment.

In one configuration, a substrate made of stainless steel is used, thereby providing magnetic and corrosion-resistant properties. A disadvantage with this configuration is the high cost of the stainless steel compared to, for example, mild steel.

Therefore, the inventors herein have recognized a need for a cost efficient substrate configuration that provides desirable magnetic properties and corrosion-resistance.

### SUMMARY OF THE INVENTION

A semiconductor device is provided in accordance with an exemplary embodiment. The semiconductor device includes a semiconductive layer disposed over a multi-layer substrate. The multi-layer substrate includes a plurality of dissimilar regions, one of which is an inner magnetic region and the remainder of the multi-layer substrate is thermally symmetrical about the inner magnetic region.

A method of forming a semiconductor device is provided in accordance with another exemplary embodiment. The method includes the step of providing a multi-layer substrate, the multi-layer substrate includes a first layer of material having a magnetic property; a second layer of material disposed above the first layer; and a third layer of material disposed below the first layer, wherein the three layers are secured together. The method further includes the step of disposing a semiconductive layer over the multi-layer substrate.

### BRIEF DESCRIPTION OF THE DRAWINGS

FIGS. 1-4 are cross-sectional views of semiconductor devices each having a multi-layer substrate in accordance with an exemplary embodiment of this disclosure.

### DETAILED DESCRIPTION OF THE INVENTION

Disclosed herein are embodiments of semiconductor devices, the concepts of which have application generally to thin film electrical devices and circuitry made of inorganic and organic materials, including photovoltaic devices, etc. Exemplary embodiments of the semiconductor devices include a multi-layer substrate and at least one semiconductive layer disposed over or on the multi-layer substrate. The multi-layer substrate has an inner layer and a plurality of covering layers. The inner layer includes a material having magnetic properties. The covering layers are disposed over the inner layer, and the covering layers generally have a different material property compared to the inner layer.

In one embodiment, the inner layer is a metal with magnetic properties. In an alternative embodiment, the inner layer is a composition of materials, such as steel, with magnetic properties. The material of the inner layer with the magnetic properties may be distributed uniformly throughout the inner layer or positioned in predetermined areas of the inner layer for manufacturing purposes and/or to suit a particular configuration of the semiconductor device.

In the embodiments, the layers of the multi-layer substrate are secured together and do not separate when the multi-layer substrate is processed thereafter, such as in preparation of the multi-layer substrate for formation of the semiconductor device or during formation of the semiconductor device, unless one or more of the layers are intentionally removed from the remainder of the multi-layer substrate. The layers of the multi-layer substrate may be secured or bonded together by means well known in the art such as pressure, chemical, heat, adhesives, etc. and combinations thereof.

In the embodiments, at least two covering layers disposed over the magnetic inner layer include a material that is substantially corrosion-resistant to protect the magnetic inner layer from degradation due to corrosion. It is contemplated herein that corrosion-resistant materials include, but not limited to, stainless steels, aluminum, bronze, durimet, monel, hasteloy, titanium, cobalt, etc. and non-metals such as plastics, rubber, polymers, etc.; including combinations thereof. In some embodiments, not all of the covering layers disposed over the inner layer will necessarily be made of corrosion-resistant materials.

In certain embodiments, a particular corrosion-resistant material of the multi-layer substrate may be selected for application in an environment having high humidity, in an environment having corrosive chemicals during a manufacturing process, during storage/transportation of the multi-layer substrate or the semiconductor device, or in an environment at an operating location of the semiconductor device. It is contemplated that in some embodiments, one or more of the covering layers will have desirable corrosion-resistance properties when the covering layer is exposed to, for non-limiting examples, acetone, ammonia, various chlorides, various acids, acidic rain, chemicals in smog, hydrogen, sulfides, hydroxides, oxygen, petroleum oils, water, steam, sea water, etc.

It is further contemplated that the corrosion-resistant material(s) selected will provide a desirable degree of resistance to corrosion in the environment of the multi-layer substrate over a predetermined duration such as during storage, during manufacturing and in the operating environment of the semiconductor device. The predetermined time may range from, for example, seconds such as during a manufacturing process, days or months during storage, or for a duration at the semiconductor device operating environment which may be covered under a warranty such as 1, 5, 10 or 20 years. Additionally, one of the covering layers may have a predetermined configuration (composition, thickness, etc.) so that in the event of some degradation of the covering layer exposed to a corrosive environment the semiconductor device is not rendered inoperable. For instance in a non-limiting example, a semiconductor device may not be rendered inoperable even though a covering layer (e.g. a mounting surface of the semiconductor device) experiences a certain amount of corrosion.

In the embodiments, the multi-layer substrate configuration is such that thermal expansion of the substrate is substantially symmetrical about the magnetic inner layer of the substrate so that the substrate maintains a substantially flat/planar configuration when the substrate is exposed to a temperature sufficient to cause the substrate to expand. In an alternative embodiment, a substrate configuration is such that not all of the covering layers about the magnetic inner layer are the same material and/or thickness, yet the substrate maintains a substantially flat/planar configuration when the substrate is exposed to a temperature sufficient to cause the substrate to expand.

In one embodiment, the multi-layer substrate is dimensionally symmetrical about the magnetic inner layer. In other alternative embodiments, not all of the layers disposed about the magnetic inner layer are the same material and additionally may or may not be symmetrically disposed about the inner layer. For instance, one of the covering layers of the multi-layer substrate can be a polymer while another layer is metallic. In some of the embodiments, the multi-layer substrates contemplated herein are configured so one or more layers can be removed after the semiconductor device is further processed after joining the multi-layer substrate with another portion of the semiconductor device.

In the embodiments and alternatives thereof, the multi-layer substrate can be held, displaced or its position/movement controlled by the application of a magnetic field across the substrate utilizing the magnetic inner layer. The magnetic attraction force occurs effectively with the magnetic inner layer positioned between the covering layers. The application of the magnetic field with the multi-layer substrate can be useful in a manufacturing process.

The magnetic field, in a non-limiting embodiment, can be applied across the multi-layer substrate by bringing another member proximate the substrate, wherein the member has an opposite magnetic pole compared to the magnetic pole of the inner layer of the substrate. In another alternative embodiment, a magnetic field can be applied across the substrate by utilizing an electric current for the formation of the magnetic field. In a non-limiting example, the application of a magnetic filed across the multi-layer substrate finds utility in a roll-to-roll process where the multi-layer substrate is a continuous member that is directed through a plurality of processes to produce at least a portion of the semiconductor device. For instance, in an exemplary embodiment a magnetic field in a range from 1000 to 2000 Gauss is applied at one or more locations across the multi-layer substrate. In another embodiment, a first magnetic field strength is applied at one location of the multi-layer substrate while a second magnetic field strength is applied at another location of the multi-layer substrate.

Examples of a roll-to-roll process line are described in U.S. patent applications Ser. No. 10/228,542, entitled “High Throughput Deposition Apparatus,” filed on Aug. 27, 2002 and Ser. No. 11/376,997, entitled “High Throughput Deposition Apparatus with Magnetic Support,” filed on Mar. 16, 2006, the disclosures of which are incorporated herein by reference. The cited applications disclose a roll-to-roll process line for manufacturing semiconductor devices, in particular photovoltaic devices, where a pay-out unit dispenses a rolled continuous substrate toward equipment some of which includes a deposition chamber having deposition apparatus therein for the deposition of materials over the continuous substrate. At the end of the roll-to-roll process line, a take-up unit receives the processed continuous substrate and forms a rolled amount thereof.

In the embodiments of semiconductor devices contemplated herein for use with multi-layer substrates, the semiconductive layer is configured to produce and/or route electrical charge. For example, in a photovoltaic device, the semiconductive layer is a layer configured to generate electric current from photons of electromagnetic radiation incident to the semiconductive layer. In some embodiments, the semiconductor device includes another non-conductive material that does not substantially produce or route electrical charge. In the exemplary embodiments, the non-conductive material may be deposited within, on or over the multi-layer substrate. In some embodiments, the non-conductive material may be included with a portion of the semiconductive material. In a non-limiting example, a configuration of non-conductive material may employed with a configuration of conducting material to route electrical current along a predetermined path. In another non-limiting example, the non-conductive material may be employed as a component of the multi-layer substrate and function, for example, as a corrosion-resistant layer.

Hereinafter, various exemplary embodiments of multi-layer substrates are described. The elements and members shown in the referenced Figures are not drawn to scale and are shown as such for clarity purposes and not intended to convey limiting information such as shape, orientation, dimensions, weight, etc., unless otherwise mentioned in the specification. For clarity herein this disclosure, is to be understood that a second layer of material disposed on a first layer of material is also considered to be disposed over the first layer, where the second layer is in physical contact with the first layer. In another embodiment, the second layer is disposed over the first layer where the first and second layers are not in physical contact with each other. Additionally, it is intended, even though not shown in the Figures, that in some embodiments of semiconductor devices one or more additional layers of material may be included between the multi-layer substrate and the semiconductive layer (e.g. for a photovoltaic device the additional layer may be a reflective layer, seed layer, etc.) and/or one or more layers of material may be disposed over the semiconductive layer (e.g. for a photovoltaic device the additional layer may be wire, a transparent conductive oxide such as indium tin oxide (ITO), an encapsulant or protective layer, etc.).

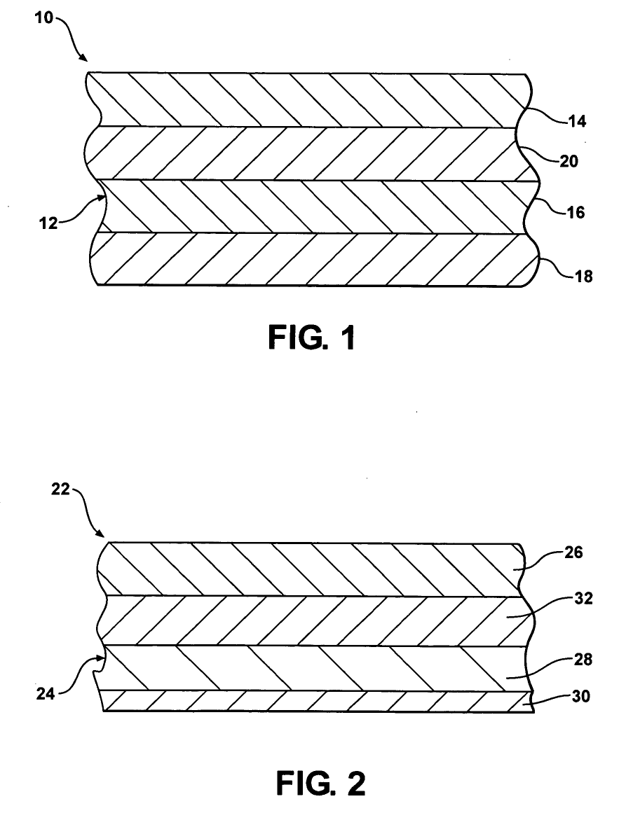

Referring to FIG. 1, a semiconductor device 10 is illustrated in accordance with an exemplary embodiment of the present disclosure. The semiconductor device 10 includes a multi-layer substrate 12 and a semiconductive layer 14 disposed over the multi-layer substrate. The multi-layer substrate 12 includes an inner layer 16, a first covering layer 18 and a second covering layer 20. The inner layer 16 is made of a material having a magnetic property. For example, in this embodiment the inner layer is stainless steel. In an alternative embodiment, the inner layer is mild carbon steel. The first covering layer 18 and the second covering layer 20 are made of a corrosion resistance material. For example, in this embodiment the first and the second covering layers are made of the same material, aluminum. In an alternative embodiment, the material of the first covering layer is different from the material of the second covering layer. The materials of the covering layers may be selected from those described hereinabove or the like.

In the embodiment of FIG. 1, the multi-layer substrate configuration is substantially symmetrical about the inner layer. In particular and in addition to the covering layers being the same material, the thickness of the first covering layer is substantially similar to the thickness of the second covering layer. The coefficient of thermal expansion of the first covering layer is substantially similar to that of the second covering layer, for aluminum material. In this configuration, the multi-layer substrate maintains a substantially flat/planar configuration when the substrate is exposed to a temperature sufficient to cause the substrate to expand.

Referring to FIG. 2, a semiconductor device 22 is illustrated in accordance with another exemplary embodiment. The semiconductor device 22 includes a multi-layer substrate 24 and a semiconductive layer 26 disposed over the multi-layer substrate. The multi-layer substrate 24 includes an inner layer 28 having magnetic properties, a first covering layer 30 and a second covering layer 32. In this embodiment, the substrate is not dimensionally symmetrical about the inner layer, but is thermally symmetrical about the inner layer. In particular and as shown, the cross-sectional thickness of the first covering layer 30 is thinner than the cross-sectional thickness of the second covering layer 32. In this embodiment, the material of the first covering layer has a coefficient of thermal expansion that is greater than the coefficient of thermal expansion of the second covering layer material such that that overall multi-layer substrate maintains a substantially flat/planar configuration when the substrate is exposed to a temperature sufficient to cause the substrate to expand.

In the configuration of FIG. 2, the materials and the thicknesses of the first and second covering layers are configured so that when the multi-layer substrate is exposed to a temperature sufficient to cause expansion of the substrate, the first and second covering layers expand substantially in a symmetrical manner about the inner layer 28. The embodiment can find utility where it may be desirable to have different first and second covering materials due to different environments above and below the inner layer, either during or after manufacturing of the substrate. For instance, the thicker, second covering layer may be desirable when the second covering layer is exposed to a more corrosive environment and/or the exposure to the corrosive environment will be for a longer duration compared to the environment and duration of exposure to corrosion associated with the first covering layer. Of course, in another alternative embodiment, layer 32 can have a thickness that is less than the thickness of layer 30, yet the multi-layer substrate maintains a substantially flat/planar configuration when the substrate is exposed to a temperature sufficient to cause the substrate to expand.

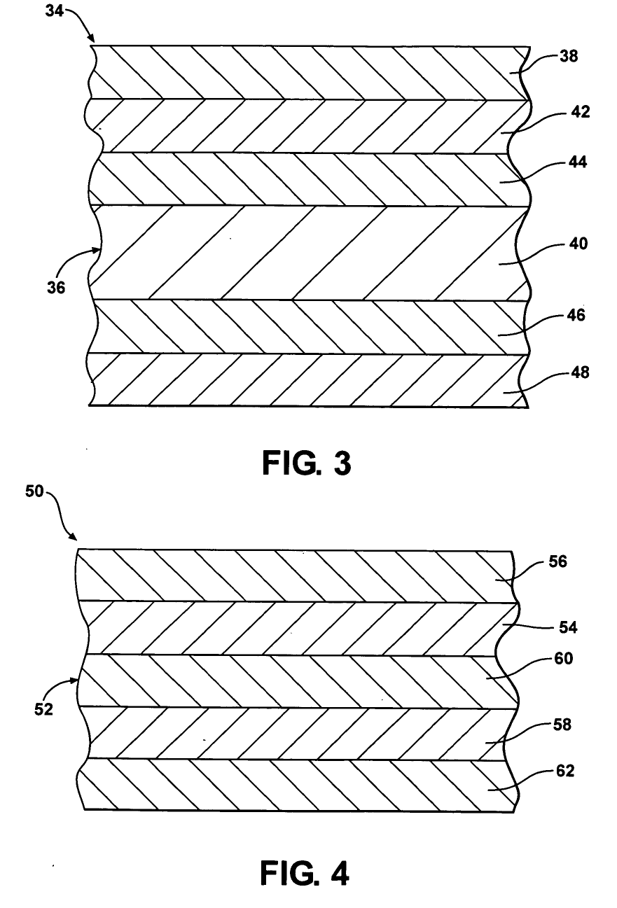

Referring to FIG. 3, a semiconductor device 34 is illustrated in accordance with another exemplary embodiment. The semiconductor device 34 includes a multi-layer substrate 36 and a semiconductive layer 38 disposed over the multi-layer substrate. The multi-layer substrate 36 includes an inner layer 40 having magnetic properties, a first upper covering layer 42, a second upper covering layer 44, a first lower covering layer 46, and a second lower covering layer 48.

In this embodiment, the material coefficients of thermal expansion and cross-sectional thicknesses of layers 42 and 48 are substantially similar to each other. The material coefficients of thermal expansion and cross-sectional thicknesses of layers 44 and 46 are substantially similar to each other, yet not the same compared to layers 42 and 48. In this embodiment, the overall multi-layer substrate maintains a substantially flat/planar configuration when the substrate is exposed to a temperature sufficient to cause the substrate to expand. A configuration such as this may be desirable where both the second upper covering layer 44 and the first lower covering layer 46 contacting the magnetic inner layer are intended to be compatible with the magnetic inner layer 40. Similarly, this configuration this may be desirable where the first upper covering layer 42 and second lower covering layer 48 are intended to be compatible with another material contacting one or both layers for a desirable configuration or characteristic of the semiconductor device. Compatibility may be expressed as a desirable aspect of the semiconductor device in terms of functionality of the device (electrical, chemical, mechanical, etc.) or an aspect desirable during manufacturing.

In another alternative of the embodiment of FIG. 3, the cross-sectional thicknesses of the upper and lower covering layers are not substantially similar, yet the overall multi-layer substrate maintains a substantially flat/planar configuration when the substrate is exposed to a temperature sufficient to cause the substrate to expand. And in another alternative embodiment, the coefficients of thermal expansion of the layers may not be the same, yet each of the thicknesses of the layers have values such that the overall multi-layer substrate maintains a substantially flat/planar configuration when the substrate is exposed to a temperature sufficient to cause the substrate to expand.

Referring to FIG. 4, a semiconductor device 50 is illustrated in accordance with another exemplary embodiment. The semiconductor device 50 includes a multi-layer substrate 52, a non-metallic layer 54 disposed over the multi-layer substrate, and a semiconductive layer 56 disposed over the non-metallic layer 54. The multi-layer substrate 52 includes an inner layer 58 having magnetic properties, a first outer covering layer 60, and second outer covering layer 62. The configuration of the multi-layer substrate 52 (such as the cross-sectional thicknesses, coefficients of thermal expansion, etc.) is such that the overall multi-layer substrate maintains a substantially flat/planar configuration when the substrate is exposed to a temperature sufficient to cause the substrate to expand.

A multi-layer substrate like that shown in FIG. 4 may find utility where one or more of the layers of the multi-layer substrate may be removed, such as by thinning, severing, etching, etc., at a later stage of manufacturing the semiconductor device. For example, the magnetic inner layer 58 and the second outer covering layer 62 will be removed in a later manufacturing process of the semiconductor device after the substrate is secured against the non-metallic layer. In a non-limiting example, the non-metallic layer 54 is a polymer and layers 58 and 62 are removed as discussed. A benefit of this configuration is a resultant lighter weight semiconductor device compared to not removing layers 58, 62 below the non-metallic layer.

A similar strategy may be employed in the configurations of the multi-layer substrates of FIGS. 1-3 or alternatives thereof, wherein one or more layers of the semiconductor device are removed after the multi-layer substrate is secured to another portion of the semiconductor device. And of course, the configuration of the semiconductor device after portions/layers are removed can be tailored so a desirable thermal performance, including deflections, results when the semiconductor device is subjected to a temperature sufficient to cause thermal expansion of the semiconductor device.

In yet another alternative embodiment, layer 60 (of the multi-layer substrate) can comprise two layers, a stress-balancing layer that contacts the non-metallic layer and a corrosion-resistant layer that contacts the magnetic inner layer. The stress-balancing layer may be utilized to minimize internal stresses in a remaining portion of the semiconductor device, for example to minimize curl of the device. For instance, the stress-balancing layer is a zinc oxide and the corrosion-resistant layer is titanium. Here, the titanium layer protects the inner layer from corrosion. Additionally, the layer contacting the inner layer, here titanium, can serve as an etch-stop, where an etching process used to remove the magnetic inner layer is not suitable to remove the titanium layer. In certain embodiments, one or more of the layers formed over the multi-layer substrate can be formed via a roll and bake process.

In another alternative embodiment, a layer that contacts the non-metallic layer is corrosion-resistant and/or serves as an etch-stop layer. And in another embodiment, one or more layers, positioned between the non-metallic layer and the multi-layer substrate, are not a part of the multi-layer substrate yet still function as a stress-balancing layer and/or an etch stop layer. It is to be understood that in the embodiments where layers between the non-metallic layer and the magnetic layer are a part of the multi-layer substrate, the coefficients of thermal expansion and thicknesses of the material layers are configured such that the overall multi-layer substrate maintains a substantially flat/planar configuration when the substrate is exposed to a temperature sufficient to cause the substrate to expand.

Examples of thinning, severing, and otherwise removing portions of substrates are described in U.S. Pat. No. 6,767,762, entitled “Lightweight Semiconductor Device and Method for its Manufacture,” and U.S. Pat. No. 7,176,543, entitled “Method of Eliminating Curl for Devices on Thin Flexible Substrates, and Devices made Thereby,” the disclosures of which are incorporated herein by reference.

In an exemplary embodiment, a method for forming a semiconductor device, such as a photovoltaic device having a multi-layered substrate will now be described. In a first step, one or more exposed surfaces of the multi-layered substrate are treated in a manner to prepare the multi-layer substrate for a subsequent processing step in forming the semiconductor device. For example, the surface is chemically treated, cleaned, washed, etched, etc. to remove and/or modify at least a portion of the surface. In another example, the surface is mechanically treated, such as polishing, buffing, etc. to prepare the multi-layered substrate for a subsequent processing step in forming the semiconductor device.

In another non-limiting example, the multi-layered substrate or a portion thereof is exposed to a plasma process, such as argon plasma, a sputtering process or the like, to modify at least a portion of the composition of the multi-layered substrate. For instance, a multi-layer substrate with an aluminum outer layer can have an outer surface of the outer layer treated by sputtering aluminum over the aluminum surface to a degree sufficient to break down the native insulating oxide of the aluminum outer layer. This process has been shown to produce a modification of the surface that is not expected and therefore the surface has a more desirable interaction with another material thereafter deposited over the treated aluminum outer layer.

In a subsequent step of forming the semiconductor device, a semiconductive layer(s), and/or a non-conductive layer(s) of material is deposited on or over the multi-layer substrate. For example, where the semiconductor device is a photovoltaic device having a tandem or triad configuration of n-p, n-i-p and p-i-n junctions, deposited materials can include crystalline silicon, amorphous silicon, microcrystalline silicon, nanocrystalline silicon, polycrystalline silicon, group IV semiconductor materials including hydrogenated alloys of silicon and/or germanium. Other photovoltaic materials include GaAs (Gallium Arsenide), CdS (Cadmium Sulfide), CdTe (Cadmium Telluride), CuInSe₂ (Copper Indium Diselenide or “CIS”), and Copper Indium Gallium Diselenide (“CIGS”), and hybrid organic/inorganic materials, for example, dye sensitive solar cells (DSSC). And in another subsequent step, additional materials or components may be formed over the semiconductive layer(s) to further form the semiconductor device.

Depending on the embodiment of semiconductor device, another subsequent step of forming the semiconductor device may be employed where one or more layers is later removed from the formed semiconductor device by the methods discussed hereinabove or by other methods depending on the configuration of the semiconductor device.

While the foregoing description has been directed to certain embodiments of a semiconductor device having a multi-layer substrate wherein the substrate includes a plurality of dissimilar regions one of which is an inner magnetic region, the principles of this invention are applicable to other embodiments of substrates and semiconductor devices not disclosed herein. In view of the teachings presented herein, yet other modifications and variations of the invention will be apparent to those of skill in the art. The foregoing is illustrative of particular embodiments, but is not meant to be a limitation upon the practice thereof. It is the following claims, including all equivalents, which define the scope of the invention.

What is claimed is:

1. A semiconductor device, comprising:
a multi-layer substrate comprising an inner layer having a magnetic property; a first covering layer disposed over a first surface of the inner layer; and a second covering layer disposed over a second surface of the inner layer; and
a semiconductive layer disposed over the multi-layer substrate.

2. The semiconductor device of claim 1, wherein the inner layer includes a steel material.

3. The semiconductor device of claim 1, wherein the first covering layer includes a corrosion-resistant material and the second covering layer is not a corrosion-resistant material.

4. The semiconductor device of claim 3, further comprising a third covering layer having a corrosion-resistant material disposed over the second covering layer.

5. The semiconductor device of claim 1, wherein the first covering layer includes a corrosion-resistant material and the second covering layer includes a corrosion-resistant material.

6. The semiconductor device of claim 5, wherein the first covering layer is a metal or metal alloy and the second covering layer is non-metallic.

7. The semiconductor device of claim 5, wherein one of the first covering layer or the second covering layer includes aluminum.

8. The semiconductor device of claim 7, wherein the inner layer includes steel.

9. The semiconductor device of claim 1, wherein the multi-layer substrate has an unsymmetrical configuration.

10. The semiconductor device of claim 9, wherein the multi-layer substrate is materially unsymmetrical about the inner layer.

11. The semiconductor device of claim 1, wherein the first covering layer and the second covering layer have a substantially similar material composition.

12. The semiconductor device of claim 1, wherein the first covering layer and the second covering layer have a substantially similar cross-sectional thickness.

13. The semiconductor device of claim 1, wherein the first covering layer and the second covering layer have a substantially similar coefficient of thermal expansion.

14. The semiconductor device of claim 1, wherein one of the first covering layer or the second covering layer is a non-metallic material.

15. The semiconductor device of claim 1, further comprising a third covering layer secured to either the first or the second covering layer.

16. The semiconductor device of claim 15, wherein the third covering layer is non-metallic.

17. The semiconductor device of claims 1- 16, wherein the semiconductive layer is disposed over the multi-layer substrate.

18. The semiconductor device of claim 1, wherein the semiconductive layer includes a non-single crystalline silicon based semiconductor material.

19. The semiconductor device of claim 18, wherein the non-single crystalline silicon based semiconductor contains a microcrystalline phase material.

20. The semiconductor device of claim 1, wherein the semiconductive layer includes an amorphous phase material.

21. The semiconductor device of claim 1, further comprising a non-conductive material.

22. The semiconductor device of claim 21, wherein the non-conductive material is disposed over the multi-layer substrate.

23. The semiconductor device of claims 1, wherein the multi-layer substrate is a continuous elongated member.

24. The semiconductor device of claim 23, wherein the semiconductive layer includes a photovoltaic material disposed above multi-layer substrate.

25. The semiconductor device of claim 24, wherein the semiconductor device is a photovoltaic device.

26. The semiconductor device of claim 24, wherein the photovoltaic materials are disposed over multi-layer substrate via a roll-to-roll process.

27. The semiconductor device of claim 1, wherein the semiconductive layer includes a photovoltaic material disposed above multi-layer substrate.

28. A method of forming a semiconductor device, the method comprising the steps of:
providing a multi-layer substrate, the multi-layer substrate comprising a first layer of material having a magnetic property; a second layer of material disposed above the first layer; and a third layer of material disposed below the first layer, wherein the three layers are secured together; and
disposing a semiconductive layer over the multi-layer substrate.

29. The method of claim 28, further comprising, prior to the step of disposing the semiconductive layer, treating a surface of the multi-layer substrate.

30. The method of claim 29, wherein the treating step includes an etching of the surface of the multi-layer substrate.

31. The method of claim 29, wherein the treating step includes exposing the surface of the multi-layer substrate to plasma.

32. The method of claim 29, wherein the treating step includes exposing the surface of the multi-layer substrate to a mechanical process.

33. The method of claim 28, further comprising applying heat to the multi-layer substrate.

34. The method of claim 28, further comprising forming another layer of material over the multi-layer substrate via a roll and bake process.

35. The method of claim 28, wherein the step of disposing the semiconductive layer of material is via a roll-to-roll process.

36. The method of claim 28, further comprising forming another layer of material over the multi-layer substrate via a roll-to-roll process.

37. The method of claim 28, further comprising forming a layer of a non-conductive material over the multi-layer substrate.

38. The method of claim 28, wherein the semiconductive layer includes a f photovoltaic material.

39. The method of claim 28, wherein at least a portion of the substrate is removed after a processing step is performed on the semiconductor device after the step of disposing the semiconductive layer over the multi-layer substrate.

40. A semiconductor device, comprising:
a multi-layer substrate comprising a plurality of dissimilar regions, one of which is an inner magnetic region and the remainder of the multi-layer substrate is thermally symmetrical about the inner magnetic region; and
a semiconductive layer disposed over the multi-layer substrate.
